(19) United States
(12) Patent Application Publication
(10) Pub. No.: US 2026/0063985 A1
(43) Pub. Date: Mar. 5, 2026

(54) PHOTOMASK, AND PHOTOALIGNMENT FILM AND DIFFRACTIVE ELEMENT PRODUCED USING THE PHOTOMASK

(71) Applicant: SHARP KABUSHIKI KAISHA, Sakai City (JP)

(72) Inventors: Ryosuke SAIGUSA, Sakai City (JP); KIYOSHI MINOURA, Sakai-shi (JP); AKIRA SAKAI, Sakai City (JP); YUICHI KAWAHIRA, Sakai City (JP); Takeshi OYAMA, Sakai City (JP)

(21) Appl. No.: 19/302,434

(22) Filed: Aug. 18, 2025

(30) Foreign Application Priority Data
Aug. 27, 2024 (JP) 2024-145618

(51) Int. Cl. G03F 1/38; G02B 5/30

(52) U.S. Cl. CPC G03F 1/38; G02B 5/3016

(57) ABSTRACT

Provided are a photomask that has high light resistance and a fine structure and that can be easily produced, and a photoalignment film and a diffractive element produced using the photomask. The photomask of the present invention includes a supporting substrate and a structural birefringence layer arranged on the supporting substrate. The structural birefringence layer has a structure in which, in a plan view, repeating unit structures are periodically arranged. The repeating unit structures each have a structure in which, in a plan view, optical unit structures with slow axes at different azimuthal angles are arranged along an arrangement direction of the repeating unit structures. The optical unit structures each have a structure in which regions with different refractive indices are alternately arranged. The slow axes of the optical unit structures are each not perpendicular to the arrangement direction in a plan view.

### CROSS-REFERENCE TO RELATED APPLICATIONS

The present application claims priority under 35 U.S.C. § 119 to Japanese Patent Application No. 2024-145618 filed on Aug. 27, 2024, the contents of which are incorporated herein by reference in their entirety.

### BACKGROUND OF THE INVENTION

### Field of the Invention

The following disclosure relates to a photomask and a photoalignment film and a diffractive element produced using the photomask.

### Description of Related Art

Patent Literature 1 discloses a liquid crystal element including: a transparent substrate; a liquid crystal layer including: a liquid crystal material; and a concavo-convex portion including periodic concaves and convexes, wherein the concavo-convex portion of the liquid crystal layer is aligned so that a longitudinal direction of liquid crystal molecules that are positioned on a side of the transparent substrate and on a concavo-convex surface that is an interface of the concavo-convex portion substantially becomes a vertical direction with respect to a concavo-convex surface on the side of the transparent substrate to form a diffraction grating, or the concavo-convex portion of the liquid crystal layer is aligned so that a longitudinal direction of liquid crystal molecules that are positioned on a side, in which a medium is disposed and which is opposite to the transparent substrate, and on the concavo-convex surface that is the interface of the concavo-convex portion substantially becomes the vertical direction with respect to a concavo-convex surface on the side, in which the medium is disposed, to form a diffraction grating.

### SUMMARY

To produce augmented reality (AR) glasses using a light guide plate, a diffractive element is required to trap light from the light source in the light guide plate. The diffractive element has a submicron-scale periodic structure and can be obtained, for example, by forming a film of a polymerizable liquid crystal on a photoalignment film in which the azimuth of the alignment regulating force periodically rotates in a uniaxial direction in a plan view. The photoalignment film in which the azimuth of the alignment regulating force periodically rotates in a plan view (periodically patterned photoalignment film) can be obtained, for example, by photoalignment treatment using a polarization-dependent diffractive element as a photomask.

The polarization-dependent diffractive element may be, for example, a patterned phase difference plate containing a polymerizable liquid crystal whose alignment azimuth periodically rotates in a uniaxial direction in a plan view. However, since liquid crystals degrade due to absorption of ultraviolet light, resulting in a reduced phase difference, polarization-dependent diffractive elements containing polymerizable liquid crystals may suffer from insufficient light resistance. The polarization-dependent diffractive element may also be a patterned phase difference plate exhibiting structural birefringence. However, production of a patterned phase difference plate having a structural birefringence is challenging due to the need for submicron-scale structures.

In response to the above current situations, embodiments of the present invention aims to provide a photomask that has high light resistance and a fine structure and that can be easily produced, and a photoalignment film and a diffractive element produced using the photomask.

(1) One embodiment of the present invention is directed to a photomask including: a supporting substrate; and a structural birefringence layer arranged on the supporting substrate, the structural birefringence layer having a structure in which, in a plan view, repeating unit structures are periodically arranged, the repeating unit structures each having a structure in which, in a plan view, optical unit structures with slow axes at different azimuthal angles are arranged along an arrangement direction of the repeating unit structures, the optical unit structures each having a structure in which regions with different refractive indices are alternately arranged, the slow axes of the optical unit structures each being not perpendicular to the arrangement direction in a plan view.

(2) In an embodiment of the present invention, the photomask includes the structure (1), and when the arrangement direction in a plan view is defined as a 0°-180° azimuthal angle direction, and in each of the repeating unit structures, the number of the optical unit structures is defined as k, and the azimuthal angle of the slow axis of one of the optical unit structures is defined as a, then the azimuthal angle of the slow axis of each of the optical unit structures, denoted as azimuthal angle A, satisfies the following Expression 1 and Expression 2:

$$azimuthal angle A = α + 180 ° \times i \div k \qquad ( Expression 1 )$$

$$azimuthal angle A \neq 90 ° \qquad ( Expression 2 )$$

where in Expression 1, k is an integer of 2 or greater, i is an integer of 0 or greater and (k−1) or less.

(3) In an embodiment of the present invention, the photomask includes the structure (2), and the azimuthal angle A satisfies the following Expression 2-1 or Expression 2-2:

$$azimuthal angle A < 85 ° \qquad ( Expression 2 - 1 )$$

$$95 ° < azimuthal angle A . \qquad ( Expression 2 - 2 )$$

(4) In an embodiment of the present invention, the photomask includes the structure (2) or (3), the azimuthal angle A satisfies the following Expression 3:

$$azimuthal angle A \neq 0 ° . \qquad ( Expression 3 )$$

(5) In an embodiment of the present invention, the photomask includes the structure (4), and the azimuthal angle A satisfies the following Expression 3-1:

$$5 ° < azimuthal angle A < 175 ° . \qquad ( Expression 3 - 1 )$$

(6) In an embodiment of the present invention, the photomask includes the structure (1), (2), (3), (4), or (5), in each of the repeating unit structures, the optical unit structures include a first optical unit structure with a first slow axis, a second optical unit structure with a second slow axis, a third optical unit structure with a third slow axis, and a fourth optical unit structure with a fourth slow axis, and when the arrangement direction in a plan view is defined as a 0°-180° azimuthal angle direction, then an azimuthal angle of the first slow axis is 22.5°, an azimuthal angle of the second slow axis is 67.5°, an azimuthal angle of the third slow axis is 112.5°, and an azimuthal angle of the fourth slow axis is 157.5°.

(7) In an embodiment of the present invention, the photomask includes the structure (1), (2), (3), (4), (5), or (6), and in each of the optical unit structures, the regions include two or more first regions and two or more second regions, and the first regions have a different refractive index from the second regions.

(8) In an embodiment of the present invention, the photomask includes the structure (7), the first regions have a refractive index equal to or less than a refractive index of air, and the second regions have a refractive index greater than the refractive index of air.

(9) In an embodiment of the present invention, the photomask includes the structure (7) or (8), and the first regions are air layers.

(10) In an embodiment of the present invention, the photomask includes the structure (7), (8), or (9), the first regions and the second regions are alternately stacked in each of the optical unit structures, and the slow axis of each of the optical unit structures is perpendicular to a stacking direction of the first regions and the second regions.

(11) Another embodiment of the present invention is directed to a photoalignment film that has been subjected to photoalignment treatment through the photomask having any one of the structures (1), (2), (3), (4), (5), (6), (7), (8), (9), and (10).

(12) Another embodiment of the present invention is directed to a diffractive element including: a photoalignment film that has been subjected to photoalignment treatment through the photomask having any one of the structures (1), (2), (3), (4), (5), (6), (7), (8), (9), and (10); and a liquid crystal layer that is arranged on the photoalignment film and contains a polymerizable liquid crystal.

Embodiments of the present invention can provide a photomask that has high light resistance and a fine structure and that can be easily produced, and a photoalignment film and a diffractive element produced using the photomask.

### BRIEF DESCRIPTION OF THE DRAWINGS

FIG. 1 is a schematic cross-sectional view of an optical element of an embodiment.

FIG. 2 is a schematic cross-sectional view of a diffractive element of the embodiment.

FIG. 3 is a schematic cross-sectional view illustrating polarization states upon incidence of right-handed circularly polarized light on a polarization-dependent diffractive element.

FIG. 4 is a schematic cross-sectional view illustrating polarization states upon incidence of left-handed circularly polarized light on a polarization-dependent diffractive element.

FIG. 5 is a schematic diagram illustrating the patterning of linearly polarized light generated from zeroth order light and first order light emitted by a polarization-dependent diffractive element.

FIG. 6 is a schematic cross-sectional view illustrating a method for patterning the alignment regulating force in a photoalignment film using a polarization-dependent diffractive element as a photomask.

FIG. 7 is a schematic plan view of a conventional photomask that includes a liquid crystal layer containing a polymerizable liquid crystal.

FIG. 8 is a schematic cross-sectional view of the conventional photomask that includes a liquid crystal layer containing a polymerizable liquid crystal.

FIG. 9 is a schematic plan view of a photomask of the embodiment.

FIG. 10 is an enlarged schematic perspective view of the photomask of the embodiment.

FIG. 11 is a schematic perspective view of a conventional photomask including a structural birefringence layer.

FIG. 12 is a schematic plan view of the conventional photomask including a structural birefringence layer.

FIG. 13 is a schematic perspective view of an optical unit structure of Reference Example 1.

FIG. 14 is an SEM image of the optical unit structure of Reference Example 1.

FIG. 15 is a schematic perspective view of a photomask of Reference Example 2.

FIG. 16 is a polarizing microscope photograph of the photomask of Reference Example 2.

FIG. 17 is a schematic diagram illustrating a method for measuring the polarization states.

FIG. 18 is a polarizing microscope photograph of a diffractive element of Example 2.

### DETAILED DESCRIPTION OF THE INVENTION

Hereinbelow, an embodiment of the present disclosure will be described with reference to the drawings. In the drawings, identical or equivalent elements are denoted by the same reference signs, and redundant descriptions thereof are omitted. The drawings illustrate only the principal components. The following description focuses on the principal components and components relevant to the present disclosure.

Herein, the term “observer side” refers to the surface of the optical element, or the surface of a component within the optical element, that is positioned closer to the observer. The term “back surface side” refers to the surface opposite to the observer side.

### Embodiment

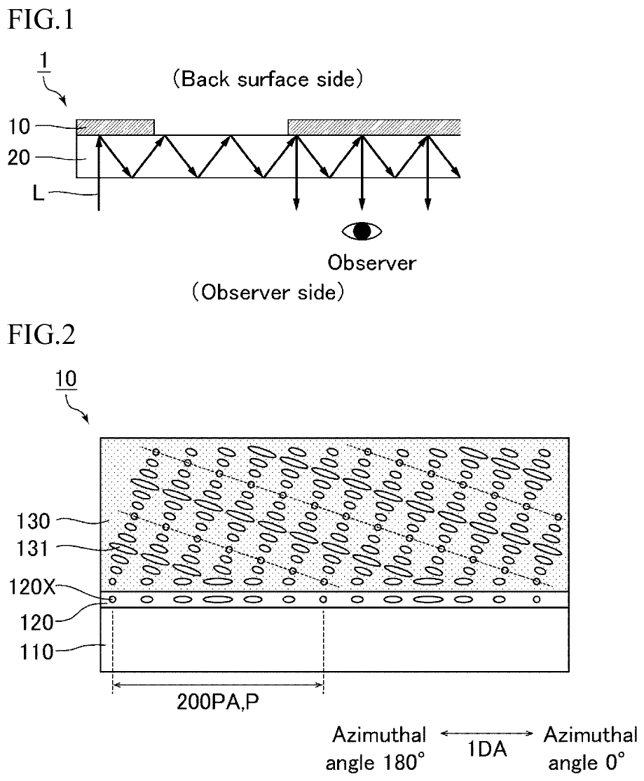

FIG. 1 is a schematic cross-sectional view of an optical element of an embodiment. FIG. 2 is a schematic cross-sectional view of a diffractive element of the embodiment. As shown in FIG. 1, an optical element 1 of the present embodiment includes a light guide plate 20 and a diffractive element 10 arranged on the back surface side of the light guide plate 20. The diffractive element 10 functions to trap light L, entering from the observer side, within the light guide plate 20. The light L entering the optical element 1 is trapped within the light guide plate 20 by the diffractive element 10, and is emitted to the observer side while being repeatedly reflected inside the light guide plate 20. The optical element 1 can be used, for example, as a component of augmented reality (AR) glasses.

The diffractive element 10 has a submicron-scale periodic structure. The diffractive element 10 includes, for example, as shown in FIG. 2, a supporting substrate 110, a photoalignment film 120, and a liquid crystal layer 130 in order.

Examples of the supporting substrate 110 include insulating substrates such as glass substrates and plastic substrates. The supporting substrate 110 is preferably transparent. The term “transparent” means that the total light transmittance defined in JIS7361-1 (ISO13468-1) is 85% or higher.

The liquid crystal layer 130 contains a polymerizable liquid crystal 131. The expression that the liquid crystal layer contains a polymerizable liquid crystal means that the liquid crystal layer contains a polymer of the polymerizable liquid crystal. The liquid crystal layer 130 can be obtained by forming a film of a liquid crystal material that contains a chiral agent and the polymerizable liquid crystal 131 and polymerizing the polymerizable liquid crystal 131.

The polymerizable liquid crystal 131 is not limited. Examples of the polymerizable liquid crystal 131 include conventionally known ones. The polymerizable liquid crystal 131 preferably has a mesogen group, a photoreactive group, and a polymerizable group. The mesogen group is a substituent such as, for example, a biphenyl group, terphenyl group, naphthalene group, phenyl benzoate group, azobenzene group, or a derivative of any of these groups. The photoreactive group is a substituent such as, for example, a cinnamoyl group, chalcone group, cinnamylidene group, β-(2-phenyl) acryloyl group, cinnamic acid group, or a derivative of any of these groups. The polymerizable group is a substituent such as, for example, an acrylate group, methacrylate group, maleimide group, N-phenylmaleimide group, siloxane group, or a derivative of any of these groups.

The polymerizable liquid crystal 131 is, for example, in the form of monomers. The number of polymerizable groups per molecule of the polymerizable liquid crystal 131 is not limited, but is preferably one or two.

The chiral agent is not limited. Examples of the chiral agent include those conventionally known. The chiral agent is, for example, S-811 (available from Merck KGaA).

The photoalignment film 120 is an alignment film obtained by forming a film of a photoalignment film material and subjecting the film to photoalignment treatment, thereby having a function of aligning liquid crystal molecules (for example, polymerizable liquid crystal 131) in a specific direction. The photoalignment film material encompasses general materials that undergo a structural change when irradiated with light (electromagnetic waves) such as ultraviolet light or visible light, and thereby exhibit the property of regulating the alignment of the nearby liquid crystal molecules (alignment regulating force) or change the level and/or direction of the alignment regulating force. The photoalignment film material has, for example, a photoreactive site which undergoes a reaction such as dimerization (formation of dimers), isomerization, photo-Fries rearrangement, or decomposition when irradiated with light.

Examples of a photoreactive site (functional group) that is dimerized and isomerized when irradiated with light include a cinnamate group, a chalcone group, a coumarin group, a stilbene group (cinnamate, cinnamoyl, 4-chalcone, coumarin, and stilbene). Examples of the photoreactive site (functional group) that is isomerized when irradiated with light include an azobenzene group (azobenzene). Examples of a photoreactive site that is photo-Fries rearranged when irradiated with light include a phenolic ester group (phenolic ester structure). Examples of a photoreactive site that is decomposed when irradiated with light include a cyclobutane ring group (dianhydride containing a cyclobutane ring, such as 1,2,3,4-cyclobutanetetracarboxylic-1,2:3,4-dianhydride (CBDA)).

As shown in FIG. 2, the photoalignment film 120 has a structure in which, in a plan view, photoalignment film repeating unit structures 200PA are periodically arranged, and the photoalignment film repeating unit structures 200PA each have a structure in which, in a plan view, alignment regions with an alignment regulating force 120X at different azimuthal angles are arranged along an arrangement direction 1DA of the photoalignment film repeating unit structures 200PA. In each of the photoalignment film repeating unit structures 200PA, in a plan view, the azimuthal angle of the alignment regulating force 120X rotates by 180° along the arrangement direction 1DA. In other words, in the entire photoalignment film 120, the azimuth of the alignment regulating force 120X periodically rotates in a uniaxial direction in a plan view (specifically, along the arrangement direction 1DA).

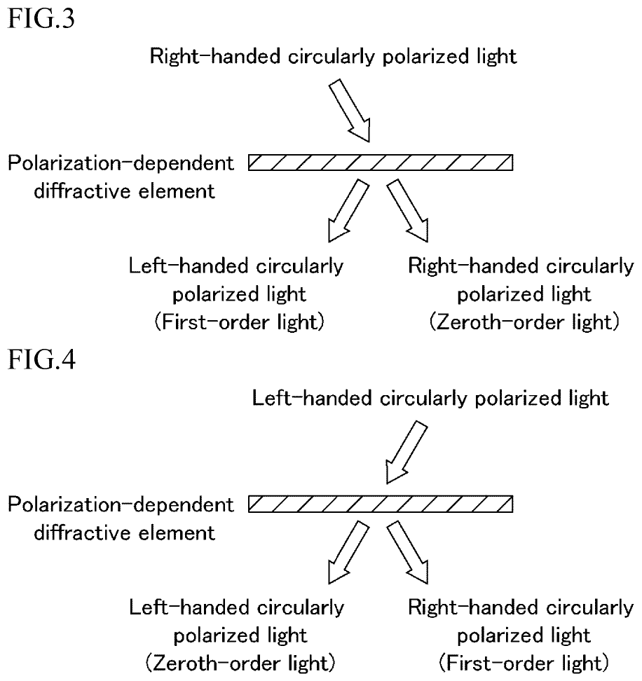

The alignment regulating force of the photoalignment film may be patterned by exposing the photoalignment film to light through a polarization-dependent diffractive element used as a photomask. FIG. 3 is a schematic cross-sectional view illustrating polarization states upon incidence of right-handed circularly polarized light on a polarization-dependent diffractive element. FIG. 4 is a schematic cross-sectional view illustrating polarization states upon incidence of left-handed circularly polarized light on a polarization-dependent diffractive element. The polarization-dependent diffractive element has a phase difference and has a structure in which the azimuth of the slow axis periodically rotates in a uniaxial direction in a plan view. As shown in FIG. 3 and FIG. 4, when circularly polarized light enters the polarization-dependent diffractive element, the light is split into zeroth-order light and first-order light. The zeroth-order light is circularly polarized light retaining the same handedness as the incident light, whereas the first-order light is circularly polarized light with the opposite handedness to the incident light.

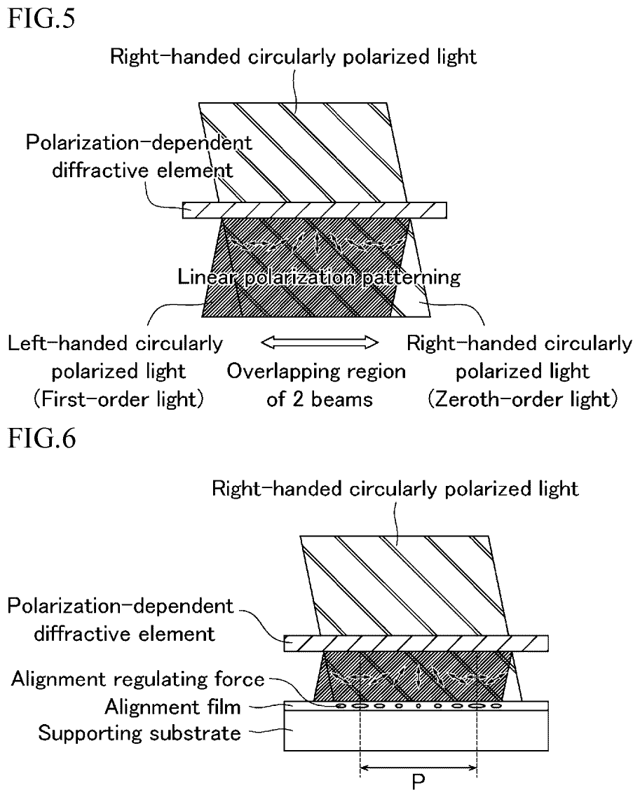

FIG. 5 is a schematic diagram illustrating the patterning of linearly polarized light generated from zeroth order light and first order light emitted from a polarization-dependent diffractive element. The ratio of the first-order light to the transmitted light intensity is defined as the diffraction efficiency, which depends on the phase difference and reaches 50% when the phase difference is one-quarter of the wavelength. When the beam diameter of light entering the polarization-dependent diffractive element is sufficiently large, as shown in FIG. 5, right-handed circularly polarized light and left-handed circularly polarized light (zeroth-order light and first-order light) overlap. The overlapping of circularly polarized lights results in linearly polarized light, whose polarization axis azimuth periodically rotates in a uniaxial direction in a plan view. The periodic pattern of the resulting linearly polarized light matches the periodic pattern of the polarization-dependent diffractive element.

FIG. 6 is a schematic cross-sectional view illustrating a method for patterning the alignment regulating force in a photoalignment film using a polarization-dependent diffractive element as a photomask. When the photoalignment film is irradiated with circularly polarized light through a polarization-dependent diffractive element used as a photomask, as shown in FIG. 6, the photoalignment film is patterned with the alignment regulating force at the same pitch as that of the photomask in a region where the two beams (zeroth-order light and first-order light) overlap.

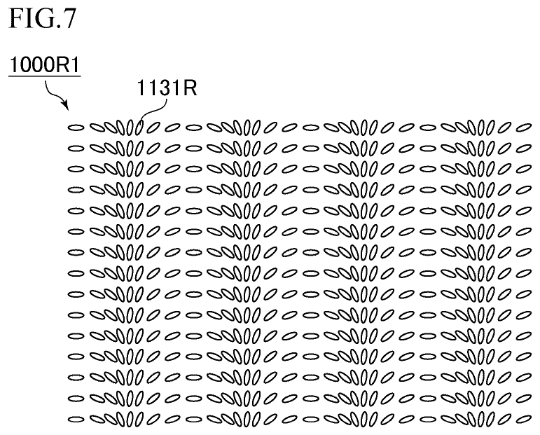

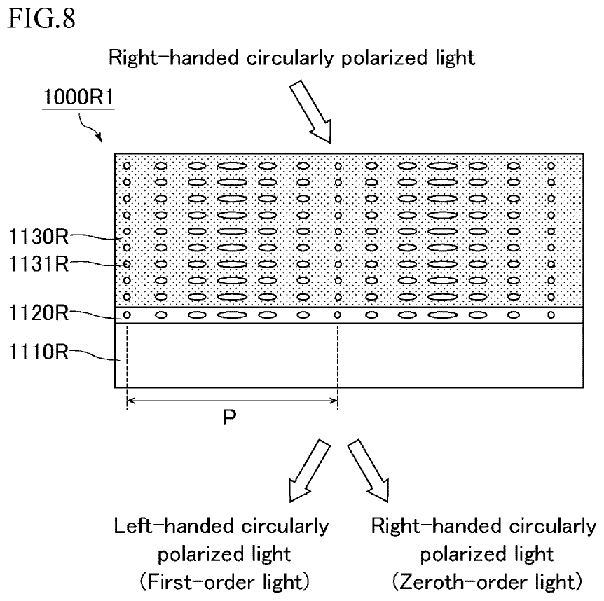

Examples of the conventional photomask include polarization-dependent diffractive elements containing a polymerizable liquid crystal. FIG. 7 is a schematic plan view of a conventional photomask that includes a liquid crystal layer containing a polymerizable liquid crystal. FIG. 8 is a schematic cross-sectional view of the conventional photomask that includes a liquid crystal layer containing a polymerizable liquid crystal. As shown in FIG. 7 and FIG. 8, a conventional photomask 1000R1 includes, for example, a supporting substrate 1110R, a photoalignment film 1120R, a liquid crystal layer 1130R containing a polymerizable liquid crystal 1131R in order. The photomask 1000R1 containing the polymerizable liquid crystal 1131R has a phase difference. The azimuth of the slow axis of the polymerizable liquid crystal 1131R periodically rotates in a uniaxial direction in a plan view.

When the photoalignment film is exposed to light through the conventional photomask 1000R1, the polymerizable liquid crystal 1131R deteriorates under light (ultraviolet light, UV) at the photosensitive wavelength of the photoalignment film. The deterioration leads to a reduction in the phase difference of the photomask 1000R1, making mass production of the photoalignment film 120 using the conventional photomask 1000R1 challenging.

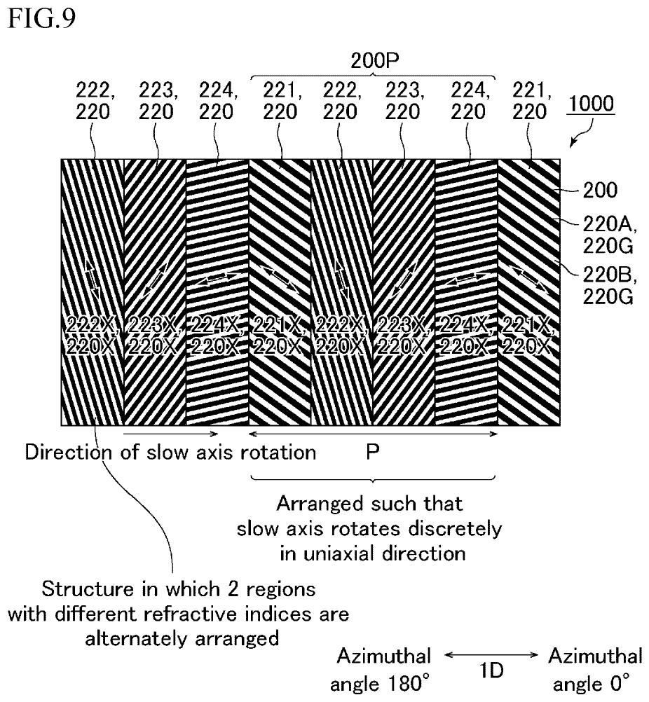

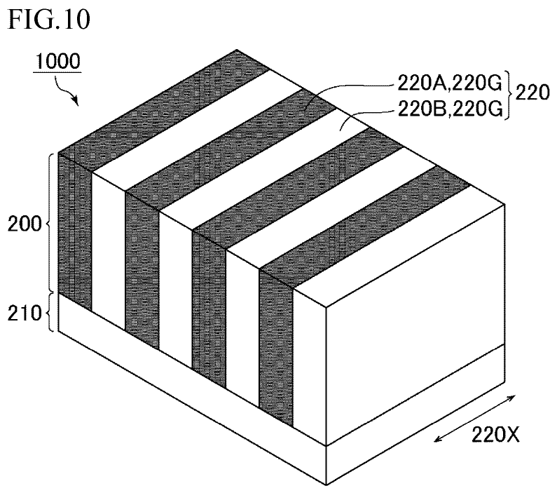

In contrast, the photomask 1000 of the present embodiment includes, as shown in FIG. 9 and FIG. 10, a supporting substrate 210, and a structural birefringence layer 200 arranged on the supporting substrate 210. The structural birefringence layer 200 has a structure in which, in a plan view, repeating unit structures 200P are periodically arranged. The repeating unit structures 200P each have a structure in which, in a plan view, optical unit structures 220 with slow axes 220X at different azimuthal angles are arranged along an arrangement direction 1D of the repeating unit structures 200P. The optical unit structures 220 each have a structure in which regions 220G with different refractive indices are alternately arranged. Such a structural birefringence layer 200 exerts structural birefringence due to the difference in refractive index between the regions 220G, thus exhibiting a phase difference. In other words, the photomask 1000 of the present embodiment exhibits a phase difference not owing to a liquid crystal layer containing a polymerizable liquid crystal but owing to the structural birefringence layer 200. Thus, the photomask 1000 can suppress a reduction in phase difference under ultraviolet light, thus achieving favorable light resistance. The photomask 1000 of the embodiment therefore enables mass production of the photoalignment film 120. FIG. 9 is a schematic plan view of the photomask of the embodiment. FIG. 10 is an enlarged schematic perspective view of the photomask of the embodiment.

In addition, in a plan view, the slow axis 220X of each of the optical unit structures 220 is not perpendicular to the arrangement direction 1D.

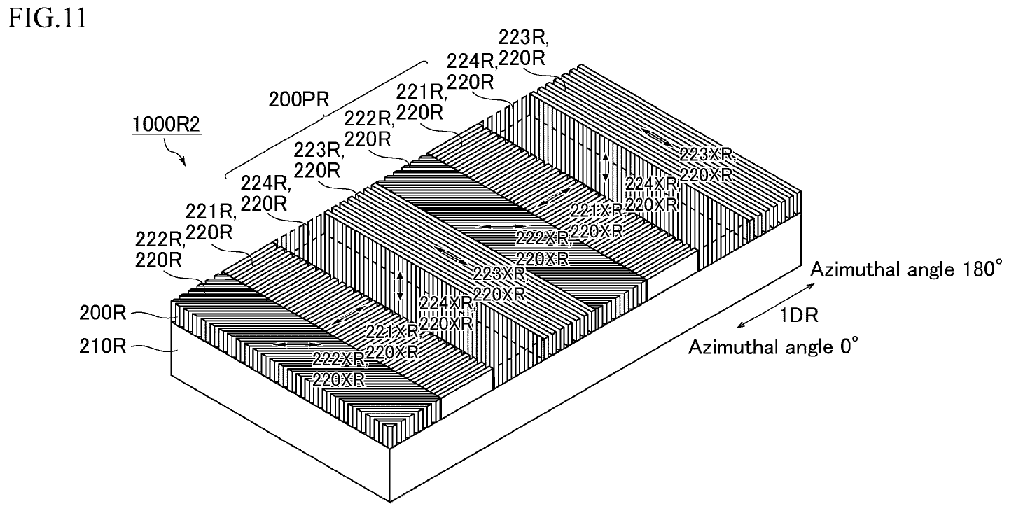

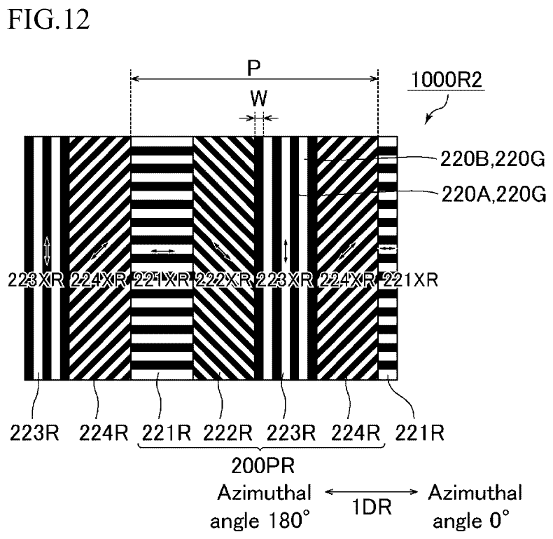

Now, a conventional photomask including a structural birefringence layer is described. FIG. 11 is a schematic perspective view of a conventional photomask including a structural birefringence layer. FIG. 12 is a schematic plan view of the conventional photomask including a structural birefringence layer.

A conventional photomask 1000R2 shown in FIG. 11 and FIG. 12 includes a supporting substrate 210R and a structural birefringence layer 200R on the supporting substrate 210R. The structural birefringence layer 200R has a structure in which, in a plan view, repeating unit structures 200PR are periodically arranged. The repeating unit structures 200PR each have a structure in which, in a plan view, the optical unit structures 220R with slow axes 220XR at different azimuthal angles are arranged along an arrangement direction 1DR of the repeating unit structures 200PR. The optical unit structures 220R each have a structure in which the regions 220G (first regions 220A and second regions 220B) with different refractive indices are alternately arranged.

Also, in a plan view, the slow axis 220XR of at least one of the optical unit structures 220R is perpendicular to the arrangement direction 1DR. Specifically, in each of the repeating unit structures 200PR in the conventional photomask 1000R2, the optical unit structures 220R include a first optical unit structure 221R with a first slow axis 221XR, a second optical unit structure 222R with a second slow axis 222XR, a third optical unit structure 223R with a third slow axis 223XR, and a fourth optical unit structure 224R with a fourth slow axis 224XR. When the arrangement direction 1DR in a plan view is defined as a 0°-180° azimuthal angle direction, the azimuthal angle of the first slow axis 221XR is 0°, the azimuthal angle of the second slow axis 222XR is 45°, the azimuthal angle of the third slow axis 223XR is 90°, the azimuthal angle of the fourth slow axis 224XR is 135°. The first optical unit structure 221R, the second optical unit structure 222R, the third optical unit structure 223R, and the fourth optical unit structure 224R can also be collectively referred to as the optical unit structures 220R. The first slow axis 221XR, the second slow axis 222XR, the third slow axis 223 XR, and the fourth slow axis 224XR can also be collectively referred to as the slow axes 220XR.

To produce the photoalignment film 120 described above, the distance (pitch P) over which the azimuth of the slow axis of an optical unit structure rotates by 180° in a uniaxial direction in a plan view needs to be submicron-scale (for example, several hundreds of nanometers). Thus, to produce the photoalignment film 120, the optical unit structures are required to have an even finer structure. However, in the conventional photomask 1000R2 including a slow axis 220XR perpendicular to the arrangement direction 1DR in a plan view, making the optical unit structures have such a finer structure is difficult.

In other words, in the conventional photomask 1000R2 shown in FIG. 11 and FIG. 12, the width W of each region 220G needs to be reduced to increase the total number of the regions 220G in the optical unit structure 220R (specifically, the third optical unit structure 223R) whose slow axis 220XR is at an azimuthal angle of 90°. The width W of each region 220G in the optical unit structure (specifically, the third optical unit structure 223R) whose slow axis 220XR is at an azimuthal angle of 90° can be represented by the following Expression 1W.

$$Width W = pitch P \div ( the number of optical unit structures in repeating unit structure ) \div ( the number of regions in optical unit structure whose slow axis is at azimuthal angle of 90 ° ) \qquad ( Expression 1 W )$$

In Expression 1W, the number of the optical unit structures 220R in the repeating unit structure 200PR in FIG. 11 and FIG. 12 is four. The number of the optical unit structures 220R in the repeating unit structure 200PR is also referred to as the number of divisions.

In contrast, in the photomask 1000 of the present embodiment, in a plan view, the slow axis 220X of each of the optical unit structures 220 is not perpendicular to the arrangement direction 1D. In the photomask 1000 having such a configuration, the total number of the regions 220G can be increased without the width W of each region 220G being narrowed in all the optical unit structures 220, so that the photomask 1000 having a fine structure (specifically, having a submicron-scale pitch) can be easily produced. Hereinbelow, the photomask 1000 of the present embodiment is described in detail.

The photomask 1000, as shown in FIG. 9 and FIG. 10, includes the supporting substrate 210 and the structural birefringence layer 200 arranged on the supporting substrate 210. The photomask 1000 is a polarization-dependent diffractive element.

Examples of the supporting substrate 210 include substrates such as glass substrates and plastic substrates. The supporting substrate 110 is preferably transparent.

The structural birefringence layer 200 has a structure in which, in a plan view, the repeating unit structures 200P are periodically arranged. The arrangement direction 1D of the repeating unit structures 200P in a plan view is set at the 0°-180° azimuthal angle direction. Herein, an azimuthal angle and an azimuth refer to those in a plan view. Herein, an angle measured clockwise from an azimuthal angle of 0° is referred to as a positive angle, and an angle measured counterclockwise from an azimuthal angle of 0° is referred to as a negative angle. The length of one period is also referred to as a pitch P. In a photomask 1000 having an elongated shape, in a plan view, the arrangement direction 1D of the repeating unit structures 200P is, for example, parallel to the longitudinal direction of the photomask 1000.

In a plan view, the arrangement direction 1D of the repeating unit structures 200P is, for example, perpendicular to the boundary between adjacent repeating unit structures 200P. In other words, the boundary between adjacent repeating unit structures 200P is set, for example, in the 90°-270° azimuthal angle direction.

Each of the repeating unit structures 200P has a structure in which, in a plan view, the optical unit structures 220 with the slow axes 220X at different azimuthal angles are arranged along the arrangement direction 1D of the repeating unit structures 200P. The arrangement direction of the optical unit structures 220 in a plan view is parallel to the arrangement direction 1D of the repeating unit structures 200P.

The azimuthal angle of the slow axis 220X of each of the optical unit structures 220, expressed as the smaller angle, is 0° or greater and less than 180° (for example, if the slow axis 220X lies in the 45°-225° direction, the azimuthal angle of the slow axis 220X is 45°, which is the smaller of the two angles, 45° and) 225°. The slow axis 220X of each of the optical unit structures 220 in a plan view is not perpendicular to the arrangement direction 1D. In the photomask 1000 having such a configuration, the total number of the regions 220G can be increased without the width W of each region 220G being narrowed in all the optical unit structures 220, so that the photomask 1000 having a fine structure (specifically, having a submicron-scale pitch) can be easily produced. The slow axis 220X of an optical unit structure 220 is parallel to the in-plane direction of the region 220G (the in-plane direction along the boundary with an adjacent region 220G).

In each of the repeating unit structures 200P, the azimuths of the slow axes 220X of the optical unit structures 220 vary such that, in a plan view, they appear to rotate by 180° in a uniaxial direction (along the arrangement direction 1D) over one pitch P. In other words, in the entire structural birefringence layer 200, the azimuths of the slow axes 220X, in a plan view, periodically rotate in a uniaxial direction (along the arrangement direction 1D).

In each of the repeating unit structures 200P, the azimuthal angles of the slow axes 220X of the optical unit structures 220, in a plan view, preferably gradually increase or decrease in a discrete manner along the arrangement direction 1D. The photomask 1000 having such a configuration can produce a diffractive element 10 suitable for AR glasses.

When the arrangement direction 1D in a plan view is defined as the 0°-180° azimuthal angle direction, and in each of the repeating unit structures 200P, the number of optical unit structures 220 is defined as k, and the azimuthal angle of the slow axis 220X of one of the optical unit structures 220 is defined as a, then the azimuthal angle of the slow axis 220X of each of the optical unit structures 220, denoted as azimuthal angle A, preferably satisfies the following Expression 1 and Expression 2. This configuration can further simplify the production of the photomask 1000 having a fine structure.

$$azimuthal angle A = α + 180 ° \times i \div k \qquad ( Expression 1 )$$

$$azimuthal angle A \neq 90 ° \qquad ( Expression 2 )$$

In Expression 1, k is an integer of 2 or greater, i is an integer of 0 or greater and (k−1) or less.

In Expression 1, k is preferably 2 or greater, more preferably 4 or greater, still more preferably 8 or greater. The upper limit of k is not limited, and is 50 or less, for example.

The azimuthal angle A preferably satisfies the following Expression 2-1 or Expression 2-2. Such a configuration can further simplify the production of the photomask 1000 having a fine structure.

$$Azimuthal angle A < 85 ° \qquad ( Expression 2 - 1 )$$

$$95 ° < azimuthal angle A \qquad ( Expression 2 - 2 )$$

The azimuthal angle A preferably satisfies the following Expression 3. In other words, preferably, none of the azimuthal angles A of the optical unit structures 220 is 0°. Such a configuration can further simplify the production of the photomask 1000 having a fine structure.

$$Azimuthal angle A \neq 0 ° \qquad ( Expression 3 )$$

The azimuthal angle A preferably satisfies the following Expression 3-1. Such a configuration can even further simplify the production of the photomask 1000 having a fine structure.

$$5 ° < Azimuthal angle A < 175 ° \qquad ( Expression 3 - 1 )$$

The azimuthal angle A more preferably satisfies the following Expression 4-1 or Expression 4-2. Such a configuration can even further simplify the production of the photomask 1000 having a fine structure.

$$5 ° < Azimuthal angle A < 85 ° \qquad ( Expression 4 - 1 )$$

$$95 ° < Azimuthal angle A < 175 ° \qquad ( Expression 4 - 2 )$$

In each of the repeating unit structures 200P, the optical unit structures 220 include a first optical unit structure 221 with a first slow axis 221X, a second optical unit structure 222 with a second slow axis 222X, a third optical unit structure 223 with a third slow axis 223X, and a fourth optical unit structure 224 with a fourth slow axis 224X. For example, the azimuthal angle of the first slow axis 221X is 22.5°, the azimuthal angle of the second slow axis 222X is 67.5°, the azimuthal angle of the third slow axis 223X is 112.5°, and the azimuthal angle of the fourth slow axis 224X is 157.5°. In the present embodiment, the azimuthal angle of 22.5° is defined as a range of 22.5°±5°, the azimuthal angle of 67.5° is defined as a range of 67.5°+5°, the azimuthal angle of 112.5° is defined as a range of 112.5°±5°, and the azimuthal angle of 157.5° is defined as a range of 157.5°±5°.

The optical unit structures 220 each have a structure in which the regions 220G with different refractive indices are alternately arranged. The optical unit structures 220 with such a configuration can exhibit a phase difference. Also, the photomask 1000 including the optical unit structures 220 with such a configuration can suppress a reduction in phase difference under ultraviolet light, and thus can exhibit favorable light resistance. The optical unit structures 220 each specifically have a structure in which the regions 220G are alternately arranged with a period on the order of the wavelength. The refractive index in the present embodiment refers to the absolute refractive index. The stacking direction of the regions 220G is parallel to the in-plane direction of the supporting substrate 210 (the in-plane direction along the boundary with the regions 220G).

In each of the optical unit structures 220, preferably, the regions 220G include two or more first regions 220A and two or more second regions 220B, and the first regions 220A have a different refractive index from the second regions 220B. In the photomask 1000 having such a configuration, each of the optical unit structures 220 can function as a phase difference plate. For example, in FIG. 9, the first optical unit structure 221, the second optical unit structure 222, the third optical unit structure 223, and the fourth optical unit structure 224 each can function as a phase difference plate. The optical unit structures 220 each preferably have a periodic structure.

Preferably, the first regions 220A have a refractive index equal to or less than the refractive index of air, and the second regions 220B have a refractive index greater than the refractive index of air. The first regions 220A are air layers, for example. The second regions 220B include, for example, an inorganic material or an organic material. Examples of the inorganic material include metal. Examples of the organic material include resin.

As described above, the diffractive element 10 suitable for AR glasses can be produced using the photomask 1000 of the present embodiment. The photoalignment film 120 included in the diffractive element 10 is a photoalignment film that has been subjected to photoalignment treatment through the photomask 1000 of the present embodiment.

The diffractive element 10 of the present embodiment includes a photoalignment film 120 that has been subjected to photoalignment treatment through the photomask 1000, and the liquid crystal layer 130 that is arranged on the photoalignment film 120 and contains the polymerizable liquid crystal 131.

The diffractive element 10 is also referred to as a liquid crystal diffractive element. When a liquid crystal diffractive element is produced on a plastic substrate, a release layer can be used. A release layer can be formed on a glass substrate, and then the photoalignment film 120 and the polymerizable liquid crystal 131 can be formed in order on the release layer. The liquid crystal layer 130 containing the polymerizable liquid crystal 131 is removed from the release layer and then transferred onto the plastic substrate, so that the liquid crystal diffractive element can be formed on the plastic substrate. In this process, it is acceptable for part of the photoalignment film 120 to remain on the release layer.

### EXAMPLES

The following describes the effect of the present invention based on examples, a comparative example, and reference examples. The present invention is not limited to these examples.

### Reference Example 1

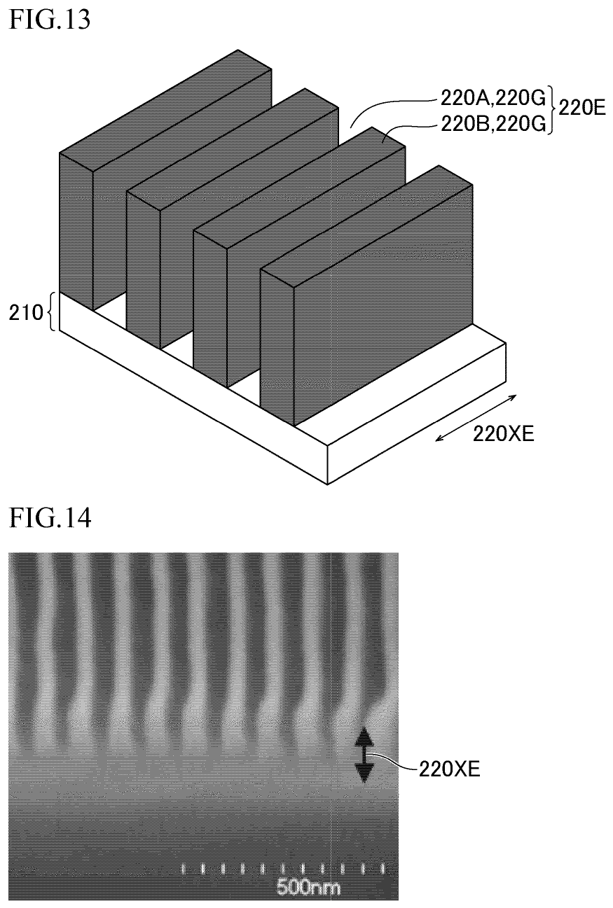

FIG. 13 is a schematic perspective view of an optical unit structure of Reference Example 1. As shown in FIG. 13, an optical unit structure 220E of the present reference example had a structure in which the first regions 220A (specifically, air layers) and the second regions 220B (specifically, resin layers) were alternately arranged in a predetermined direction, the first regions 220A having a different refractive index from the second regions 220B. The optical unit structure 220E had an uneven shape in which recesses and protrusions were repeated in the predetermined direction.

The optical unit structure 220E of the present reference example was produced by nanoimprint lithography. Specifically, a UV-curable resin was applied to a supporting substrate 210, and the UV-curable resin before curing was irradiated with ultraviolet light in a state where a mold having an uneven shape was pressed onto the resin. Next, the mold was removed, so that the optical unit structure 220E having an uneven shape was obtained. The supporting substrate 210 was a triacetyl cellulose film (TAC film). The mold was a Wire Grid polarizer (available from Edmund Optics Inc.). The irradiation with ultraviolet light was performed with an intensity of 140 mW/cm² for 7 seconds.

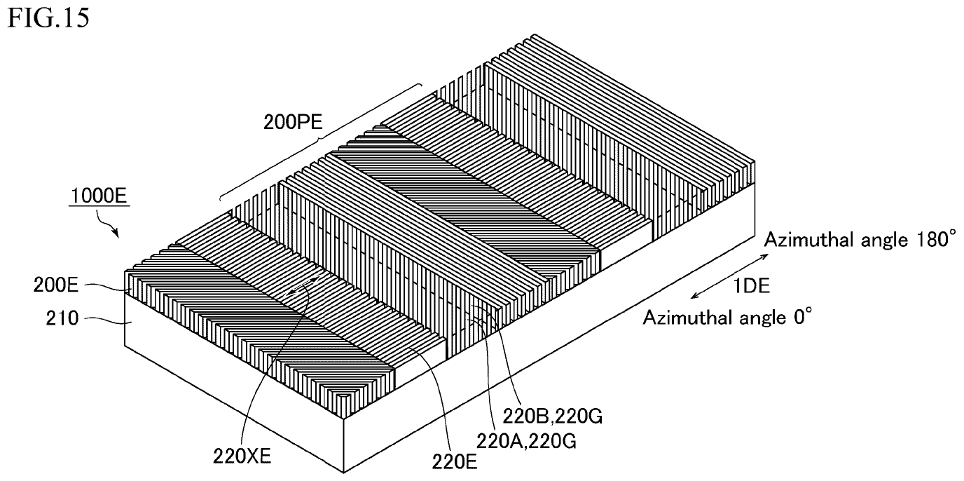

The shape of the optical unit structure 220E of the present reference example was observed under a scanning electron microscope (SEM). FIG. 14 is an SEM image of the optical unit structure of Reference Example 1. FIG. 14 shows that the optical unit structure 220E of the present reference example had the uneven shape shown in FIG. 13.

Also, the phase difference of the optical unit structure 220E was measured with Axoscan available from Axometrics Inc. The optical unit structure 220E was found to exhibit a phase difference of 8 nm at a wavelength of 550 nm. Additionally, it was found that the slow axis 220XE of the optical unit structure 220E lies in the direction indicated by the arrow in FIG. 14.

### Reference Example 2

FIG. 15 is a schematic perspective view of a photomask of Reference Example 2. As shown in FIG. 15, a photomask 1000E of the present reference example included a supporting substrate 210 and a structural birefringence layer 200E arranged on the supporting substrate 210. The structural birefringence layer 200E had a structure in which repeating unit structures 200PE were periodically arranged in a plan view. The repeating unit structures 200PE each had a structure in which, in a plan view, optical unit structures 220E with slow axes 220XE at different azimuthal angles were arranged along an arrangement direction 1DE of the repeating unit structures 200PE. The optical unit structures 220E each had a structure in which regions 220G with different refractive indices were alternately arranged.

The optical unit structures 220E in the photomask 1000E each had the same configuration as the optical unit structure 220E of Reference Example 1. In other words, the optical unit structures 220E each had a structure in which the first regions 220A (specifically, air layers) and the second regions 220B were alternately arranged in a predetermined direction. The uneven shape of the photomask 1000E of the present reference example was formed by performing electron beam (EB) lithography on a metal film. In the present reference example, the second regions 220B were metal layers.

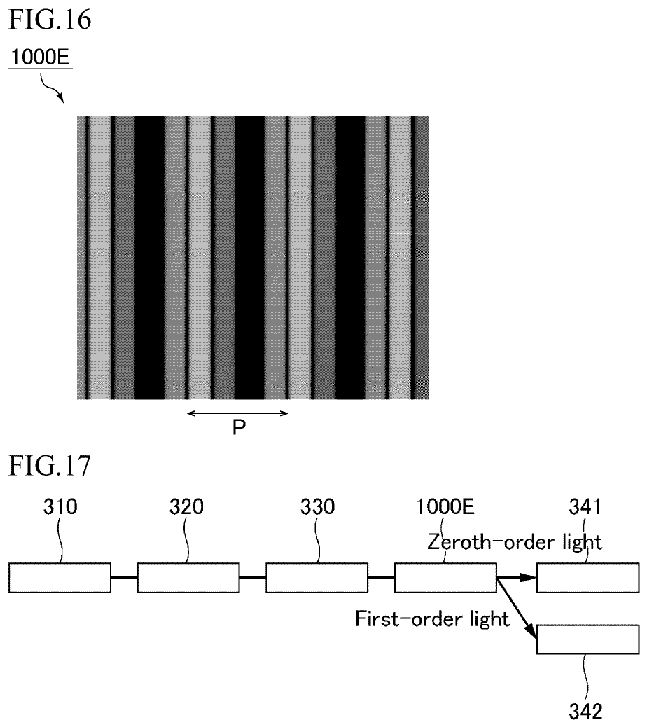

The obtained photomask 1000E was observed under a polarizing microscope. FIG. 16 is a polarizing microscope photograph of the photomask of Reference Example 2. FIG. 16 shows that the distance (pitch P) over which the azimuth of the uneven direction (slow axis) rotates by 180° is divided into four in the present reference example.

To confirm that the photomask 1000E of the present reference example function as a polarization-dependent diffractive element, the following measurement was performed. FIG. 17 is a schematic diagram illustrating a method for measuring the polarization states. As shown in FIG. 17, ultraviolet light having a wavelength of 355 nm emitted from a laser light source 310 was transmitted through a wire grid polarizer 320 and a quarter wave plate 330 (λ/4 plate) to be converted to circularly polarized light. The circularly polarized light was applied to the photomask 1000E to measure the polarization states of the incident light and zeroth-order light using a polarimeter 341 and to measure the polarization state of the first-order light using a polarimeter 342. The following Table 1 shows the results. Table 1 shows the normalized Stokes parameter S3.

TABLE 1

| | Incident light | Zeroth-order light | First-order light |
|---|---|---|---|
| S3 | +0.98 | +0.98 | −0.97 |

The closer the absolute value of S3 is to 1, the closer the polarization state is to circular polarization. The sign of S3 indicates the handedness of circular polarization. Table 1 shows that when the photomask 1000E of the present reference example was used, the zeroth-order light and the incident light exhibited circular polarization with the same handedness, while the polarization state of the diffracted light (first-order light) was opposite to that of the zeroth-order light and the incident light. These results confirmed that the photomask 1000E of the present reference example function as a polarization-dependent diffractive element. In other words, in the present reference example, the azimuths of the slow axes 220XE of the optical unit structures 220E periodically rotated in a uniaxial direction in a plan view, so that the photomask 1000E exhibited the function as a polarization-dependent diffractive element.

### COMPARATIVE EXAMPLE

A photomask of a comparative example is the conventional photomask 1000R2 obtained by setting the slow axes in the photomask 1000E of Reference Example 2 as shown in FIG. 11 and FIG. 12. In the optical unit structures 220R, as shown in FIG. 12, the first regions 220A (specifically, air layers) with a refractive index equal to the refractive index of air and the second regions 220B with a refractive index greater than the refractive index of air are alternately arranged in a predetermined direction.

In the photomask 1000R2 of the comparative example, the azimuthal angle of the first slow axis 221XR is 0°, the azimuthal angle of the second slow axis 222XR is 45°, the azimuthal angle of the third slow axis 223XR is 90°, and the azimuthal angle of the fourth slow axis 224XR is 135°.

The width of each region 220G in the photomask 1000R2 of the comparative example is examined. When the diffractive element 10, which is used to trap light in the light guide plate of AR glasses, is produced using the photomask 1000R2 of the comparative example, the pitch P of the photomask 1000R2 needs to be on a submicron scale.

For example, a case is examined in which the pitch P (the length of a repeating unit structure 200PR in the arrangement direction 1DR) is 300 nm and, as shown in FIG. 12, each repeating unit structure 200PR includes four optical unit structures 220R. The region in which the azimuthal angle of the slow axis 220XR is 90° (third optical unit structure 223R) is the focus of examination. The third optical unit structure 223R includes four layers of second regions 220B with a refractive index greater than the refractive index of air and three layers of first regions 220A with a refractive index equal to the refractive index of air, placed between the second regions 220B, i.e., seven layers of regions 220G in total.

In this case, the width W of one region 220G is approximately 10 nm, calculated as pitch (300 nm)÷number of divisions (4)÷number of regions (7). However, drawing such structures with a width on this scale is challenging. In other words, the photomask 1000R2 of the comparative example capable of producing the diffractive element 10 is difficult to produce.

### Example 1

A photomask of Example 1 corresponds to the photomask 1000 of the embodiment shown in FIG. 9 and FIG. 10, for example. A photomask 1000 of the present example is obtained by setting the slow axes in the photomask 1000E of Reference Example 2 as shown in FIG. 9. In each of the optical unit structures 220, as shown in FIG. 9, the first regions 220A (specifically, air layers) with a refractive index equal to the refractive index of air and the second regions 220B with a refractive index greater than the refractive index of air were alternately arranged in a predetermined direction.

In the photomask 1000 of the present example, the azimuthal angle of the first slow axis 221X was 22.5°, the azimuthal angle of the second slow axis 222X was 67.5°, the azimuthal angle of the third slow axis 223X was 112.5°, and the azimuthal angle of the fourth slow axis 224X was 157.5°.

In this case, the slow axis 220X of each of the optical unit structures 220 in a plan view is not perpendicular to the arrangement direction 1D. Thus, in every optical unit structure 220, the total number of the regions 220G was successfully increased without the width W of each region 220G being narrowed. In other words, in Example 1, the width W of each region 220G is not limited, so that the photomask 1000 capable of producing the diffractive element 10 having a submicron-scale periodic structure was easily produced.

### Example 2

In the present example, the diffractive element 10 of Embodiment 1 shown in FIG. 2 was produced. First, the photoalignment film 120 was patterned using the photomask 1000 of Example 1. Specifically, a photoalignment film material was applied to the supporting substrate 110 at a spin speed of 2000 rpm for 30 seconds, followed by baking at 90° C. for two minutes to form a coating film. Next, the coating film was exposed to UV light. In the UV exposure, the coating film was exposed to laser light having a wavelength of 355 nm through the photomask 1000 of Example 1.

The beam diameter of the laser light used for the UV exposure was as small as about 2 mm. Thus, the beam was expanded and collimated using a lens to match the size of the exposure region. However, the beam diameter may be smaller than the target exposure region. In this case, the entire exposure region can be exposed to UV light by scanning the exposure region with the beam. In the case of scanning exposure, unevenness in the scanning pattern may typically be observed. However, this is not problematic in the present application. This is because the process conditions for the photoalignment film to exhibit its alignment regulating force have sufficient margin. Even if the exposure conditions varied, the uneven scanning pattern would not appear after forming the polymerizable liquid crystal layer.

After the UV exposure, the coating film was baked at 160° C. for 10 minutes to obtain the photoalignment film 120.

Then, the polymerizable liquid crystal 131 was applied at a spin speed of 4500 rpm to the photoalignment film 120 formed, followed by baking at 90° C. for one minute to form a coating film. Thereafter, the coating film containing the polymerizable liquid crystal 131 was irradiated with ultraviolet light with an intensity of 100 mW/cm² for 60 seconds, so that the polymerizable liquid crystal 131 was cured into the liquid crystal layer 130. Thus, the diffractive element 10 (liquid crystal diffractive element) was obtained.

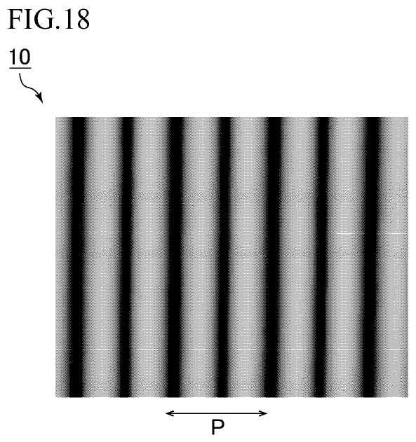

The diffractive element 10 of Example 2 was observed under a polarizing microscope. FIG. 18 is a polarizing microscope photograph of the diffractive element of Example 2. FIG. 18 shows that the diffractive element 10 of Example 2 exhibited patterned azimuths of the phase difference. In this manner, with the photomask 1000 including the structural birefringence layer 200, the diffractive element 10 (liquid crystal diffractive element) suitable for AR glasses can be produced.

An embodiment of the present disclosure has been described above. However, the present disclosure is not limited to the above embodiment and can be implemented in various forms without departing from the spirit or scope of the invention. Furthermore, the multiple components disclosed in the above embodiment may be modified as appropriate. For example, certain components from one embodiment may be added to another embodiment, or some components of an embodiment may be omitted from the embodiment.

The drawings schematically illustrate each component primarily to facilitate understanding of the invention. Therefore, the thickness, length, quantity, spacing, and other dimensions of the illustrated components may differ from actual values due to the nature of the drawing process. Furthermore, the configurations of the components shown in the above embodiment are merely examples and are not limited. Various modifications can be made without substantially departing from the spirit and scope of the present disclosure.

What is claimed is:

1. A photomask comprising:
a supporting substrate; and
a structural birefringence layer arranged on the supporting substrate,
the structural birefringence layer having a structure in which, in a plan view, repeating unit structures are periodically arranged,
the repeating unit structures each having a structure in which, in a plan view, optical unit structures with slow axes at different azimuthal angles are arranged along an arrangement direction of the repeating unit structures,
the optical unit structures each having a structure in which regions with different refractive indices are alternately arranged,
the slow axes of the optical unit structures each being not perpendicular to the arrangement direction in a plan view.

2. The photomask according to claim 1,
wherein when the arrangement direction in a plan view is defined as a 0°-180° azimuthal angle direction, and
in each of the repeating unit structures, the number of the optical unit structures is defined as k, and the azimuthal angle of the slow axis of one of the optical unit structures is defined as a, then the azimuthal angle of the slow axis of each of the optical unit structures, denoted as azimuthal angle A, satisfies the following Expression 1 and Expression 2:
$$azimuthal angle A = α + 180 ° \times i \div k \qquad ( Expression 1 )$$
$$azimuthal angle A \neq 90 ° \qquad ( Expression 2 )$$
where in Expression 1, k is an integer of 2 or greater, i is an integer of 0 or greater and (k−1) or less.

3. The photomask according to claim 2,
wherein the azimuthal angle A satisfies the following Expression 2-1 or Expression 2-2:
$$azimuthal angle A < 85 ° \qquad ( Expression 2 - 1 )$$
$$95 ° < azimuthal angle A . \qquad ( Expression 2 - 2 )$$

4. The photomask according to claim 2,
wherein the azimuthal angle A satisfies the following Expression 3:
$$azimuthal angle A \neq 0 ° . \qquad ( Expression 3 )$$

5. The photomask according to claim 4,
wherein the azimuthal angle A satisfies the following Expression 3-1:
$$5 ° < azimuthal angle A < 175 ° . \qquad ( Expression 3 - 1 )$$

6. The photomask according to claim 1,
wherein in each of the repeating unit structures, the optical unit structures include a first optical unit structure with a first slow axis, a second optical unit structure with a second slow axis, a third optical unit structure with a third slow axis, and a fourth optical unit structure with a fourth slow axis, and
when the arrangement direction in a plan view is defined as a 0°-180° azimuthal angle direction, then an azimuthal angle of the first slow axis is 22.5°, an azimuthal angle of the second slow axis is 67.5°, an azimuthal angle of the third slow axis is 112.5°, and an azimuthal angle of the fourth slow axis is 157.5°.

7. The photomask according to claim 1,
wherein in each of the optical unit structures, the regions include two or more first regions and two or more second regions, and the first regions have a different refractive index from the second regions.

8. The photomask according to claim 7,
wherein the first regions have a refractive index equal to or less than a refractive index of air, and the second regions have a refractive index greater than the refractive index of air.

9. The photomask according to claim 7,
wherein the first regions are air layers.

10. The photomask according to claim 7,
wherein the first regions and the second regions are alternately stacked in each of the optical unit structures, and
the slow axis of each of the optical unit structures is perpendicular to a stacking direction of the first regions and the second regions.

11. A photoalignment film that has been subjected to photoalignment treatment through the photomask according to claim 1.

12. A diffractive element comprising:
a photoalignment film that has been subjected to photoalignment treatment through the photomask according to claim 1; and
a liquid crystal layer that is arranged on the photoalignment film and contains a polymerizable liquid crystal.
